(19) United States
(12) Patent Application Publication
(10) Pub. No.: US 2023/0210021 A1
(43) Pub. Date: Jun. 29, 2023

(54) METHOD OF MAKING SUPERCONDUCTING INTERCONNECTIONS

(71) Applicant: COMMISSARIAT A L'ENERGIE ATOMIQUE ET AUX ENERGIES ALTERNATIVES, Paris (FR)

(72) Inventors: Nicolas POSSEME, Grenoble Cedex 09 (FR); Cyrille LE ROYER, Grenoble Cedex 09 (FR); Fabrice NEMOUCHI, Grenoble Cedex 09 (FR); Roselyne SEGAUD, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/056,318

(22) Filed: Nov. 17, 2022

(30) Foreign Application Priority Data
Nov. 18, 2021 (FR) 21 12216

(51) Int. Cl. H10N 60/85; H10N 60/01

(52) U.S. Cl. CPC H10N 60/85; H10N 60/0156

(57) ABSTRACT

The invention concerns an inteconnect device for interconnection between lines of superconducting material at least one via in contact with those lines, comprising:

a) a first substrate, which carries at least one first line of a first superconducting material;
b) at least one first via of a second superconducting material, different from the first superconducting material, said at least one first line being disposed between said first substrate and said first via;
c) at least one second line above said first via and in contact with the latter.

### TECHNICAL FIELD AND PRIOR ART

The invention concerns the production of interconnects between lines of superconducting material, these lines being located at different levels of a stack forming a circuit.

The development of spin Qbits and superconducting Qbits requires the setting up of radio-frequency compatible BEOL (“Back end of line”) routing that operates at very low temperature.

To date, BEOL integrations exist that are based on superconducting materials (Nb), but these technological stacks are not adapted to the requirements of advanced technology nodes, for example using 28 nm FD-SOI technology.

We are aware of the paper by Sergey K. Tolpygo et al., entitled “Advanced Fabrication Processes for Superconducting Very Large-Scale Integrated Circuits”, which appeared in IEEE Transactions On Applied Superconductivity, Vol. 26, NO. 3, April 2016, as well as that by S. Nagasawa et al. entitled “New Nb multi-layer fabrication process for large-scale SFQ circuits”, which appeared in Physica C 469 (2009) 1578-1584.

The technologies described in these documents do not make it possible to attain small dimensions (in particular dimensions between vias less than the urn). The connection density is also insufficient. Furthermore, the topography is too great to have multiple stacking of interconnect lines and thus to address a high level of complexity.

The problem thus arises of finding another method of producing interconnects between lines of superconducting material.

Moreover, techniques are known for producing interconnects between conventional lines of metallic materials (of non superconducting materials).

A 1^{st} example of such a technique, of “damascene” type, is illustrated in FIGS. 1A-1E, for copper lines.

This technique comprises:
producing, on a substrate 2 for example of dielectric material such as SiO₂, that can for example comprise studs 4, a lower level of metallic tracks 6, 6′ separated by zones 8 of dielectric material (FIG. 1A);
depositing, on the assembly already obtained, an etch-stop layer 10 (for example of SiCN/SiN), then a dielectric layer 12, the thickness of which is equal to that of an upper line (to be formed) of metallic tracks and a of a via (also to be formed) which connects these upper lines and one of the tracks 6, 6′; optionally a SiO₂ oxide layer 14 is deposited on the dielectric layer 12 and lastly a hard resist layer 16 of TiN is deposited (FIG. 1B);
performing a step of lithography in the layer 16 (FIG. 1C), followed by etching, in the layer 12, of the lines of an upper metallic layer then of the vias (FIG. 1D);
depositing a copper anti-diffusion barrier layer 18, 18′ (of Ta or TaN) on the free surfaces of the etched zones, then filling those etched zones by depositing copper to form metallic tracks 20, 20′ and the actual vias 22, 22′; it being possible to planarize the assembly by chemical mechanical polishing (a technique referred to as “CMP”) (FIG. 1E).

The problem with this technique is that the presence of the layer 18, 18′ in the contact zones between vias 22, 22′ and tracks 6, 6′ of the level below, increases the resistivity as well as the RC time constant of the system. The contact of the via with the lines below 6, 6′ is thus not good.

Moreover, if the dielectric material 12 is of “low k” type, the properties of that material may be modified in the etching steps; in particular, transformation may occur of part of that SiO₂ material, thereby increasing the k coefficient, which leads to an increase in the RC time constant of the final system.

A 2^{nd} example of a known technique is illustrated in FIGS. 2A-2C.

This technique comprises:
producing, on a substrate 2 for example of dielectric material such as SiO₂, and that may comprise for example studs 4, a 1^{st} metallic layer 30 in which a metallic line or lines 32 is etched, and on opposite edges of which a dielectric material 34 is deposited (FIG. 2A);
producing, on the assembly already obtained, a 2^{nd} metallic layer 36 (FIG. 2C) in which one or more vias 38 are produced (FIG. 2D);
producing, on the assembly already obtained, a 3^{rd} metallic layer 40 (FIG. 2E) in which a metallic line or lines 42 is etched, on opposite edges of which a dielectric material 44 is deposited (FIG. 2F).

This second technique comprises a greater number of steps than the first technique presented above, and a greater number of polishing steps, which gives rise to dispersion of the different layers.

The problem thus arises of finding a new method enabling the production of lines of superconducting material, these lines being located at different levels of a stack forming a circuit and being connected to each other by vias of a same superconducting material as the lines.

### DISCLOSURE OF THE INVENTION

The invention relates to an inteconnect device for interconnection between lines of superconducting material at least one via in contact with those lines, comprising:
a) a first substrate, which carries at least one first line of a first superconducting material;
b) at least one first via of superconducting material, for example a second superconducting material, different from the first superconducting material, said at least one first line being disposed between said first substrate and said first via;
c) at least one second line above said first via and in contact with the latter.

Each superconducting material may be chosen from V₃Si, CoSi₂, Nb₃Ge, TiN, NbN, Al, and TaN.

In a device according to the invention, the first superconducting material can be of, or comprise, aluminum, and the second superconducting material can be, or comprise, TiN or TaN.

A dielectric material may cover said first line and cover and/or at least laterally surround said first via.

For example, the dielectric material is:
of low dielectric constant k<7;
and/or chosen from the following list: SiN, SiCN, SiO₂, SiCOH or porous SiCOH.

A device according to the invention may comprise:
several first lines, with a pitch less than 500 nm, preferably comprised between 56 nm and 500 nm;
and/or at least one first line of thickness H₁, for example comprised between 40 nm and 300 nm.
at least one first line having a thickness H₁ and at least one via, in contact with said first line, being of thickness comprised between H₁ and H₁/2.

In a device according to the invention, said first substrate can comprise at least part of a circuit, for example at least one contact stud, with which said first line is in contact.

The invention also relates to a method of producing lines of superconducting material and via(s) connecting those lines.

According to a first aspect, such a method comprises:
a) forming, on a first substrate, a first superconducting layer of at least one superconducting material, of a thickness at least equal to the thickness of a first line and of a first via;
b) etching said superconducting layer to form first of all at least one first via; this step is for example carried out by partial etching of said superconducting layer, leaving part of that layer intact;
c) then etching said layer to form at least one first line between said first substrate and said first via; this step is for example carried out by lithography with total etching of the exposed parts of said superconducting layer to reach the substrate;
d) forming at least one second line above said first via and in contact with the latter. The vertical via is thus in contact with two lines located at two different levels.

The first substrate (S) may comprise at least part of a circuit, for example at least one contact stud, with which the first line may be in contact.

The superconducting material may be chosen from V₃Si, CoSi₂, Nb₃Ge, TiN, NbN, Al, and TaN. It may be deposited for example by PVD or CVD.

The first superconducting layer may comprise a first sub-layer of a first superconducting material, in which said first line is produced and a second sub-layer of a second superconducting material, in which said via is produced. The etching of the second superconducting sub-layer to form the via is preferably stopped on the upper surface of the first sub-layer.

Step d) of forming at least one second line may comprise forming in advance at least one second via, then the second line.

A method according to the invention may comprise, between steps c) and d), a step of covering said first line and covering and/or at least laterally surrounding said first via with a dielectric material, forming a second substrate.

This dielectric material may for example have a low relative dielectric constant k, for example k<7. It may be chosen from the following list: SiN, SiCN, SiO₂, SiCOH or porous SiCOH.

In a method according to the invention, step d) may comprise:
depositing on the second substrate a second superconducting layer of at least one superconducting material, for example one of the superconducting materials mentioned above, of thickness at least equal to the thickness of a second line, and optionally a second via;
etching the second superconducting layer to optionally form the second via, and to form at least said second line, in contact with said first via.

The second superconducting layer may comprise a first sub-layer of a first superconducting material, in which said second line is produced and a second sub-layer of a second superconducting material, in which said via is produced. Here too, the etching of the second superconducting sub-layer to form the via is preferably stopped on the upper surface of the first sub-layer.

A method according to the invention may comprise:
forming several first lines, with a pitch less than 500 nm, preferably comprised between 56 nm and 500 nm;
and/or forming at least one first line of thickness H₁ for example comprised between 40 nm and 300 nm; at least one via, in contact with said first line may have a thickness comprised between H₁ and H₁/2.

A method according to the invention requires fewer steps than a known method such as that described above in connection with FIGS. 2A-2D.

Furthermore, since the tracks of the upper metallic level are produced by successive etching operations, without requiring deposit of additional layers, the problem of dispersion of the thicknesses of the layers only has limited impact.

### BRIEF DESCRIPTION OF THE DRAWINGS

Example embodiments of the invention will now be described with reference to the accompanying drawings in which:

FIG. 1A-FIG. 1E and FIG. 2A-FIG. 2F show examples of known methods;

FIG. 3A-FIG. 3H show an example of a method and a device according to the invention;

FIG. 4A-FIG. 4B show a variant of a method and a device according to the invention;

In the Figures similar or identical technical members are designated by the same reference numbers.

### DETAILED DESCRIPTION OF EMBODIMENTS

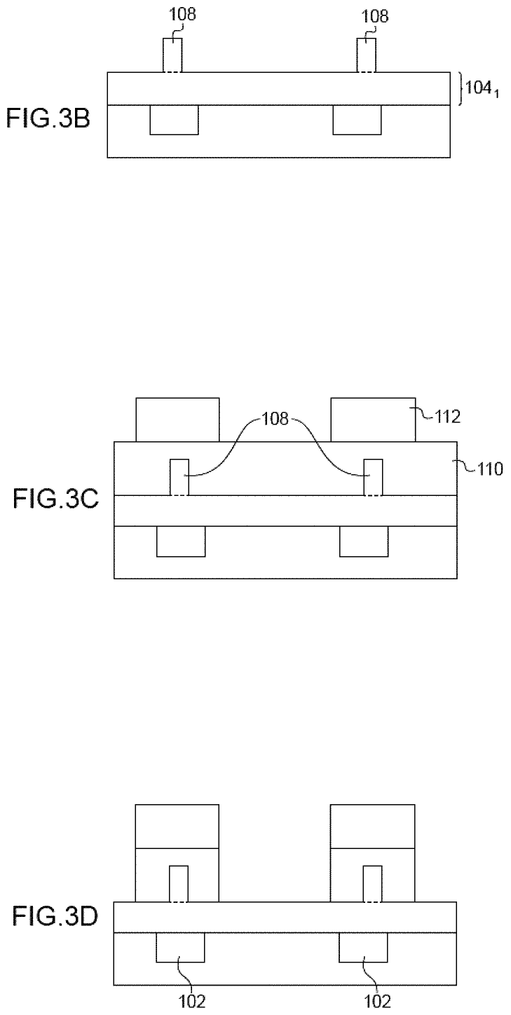

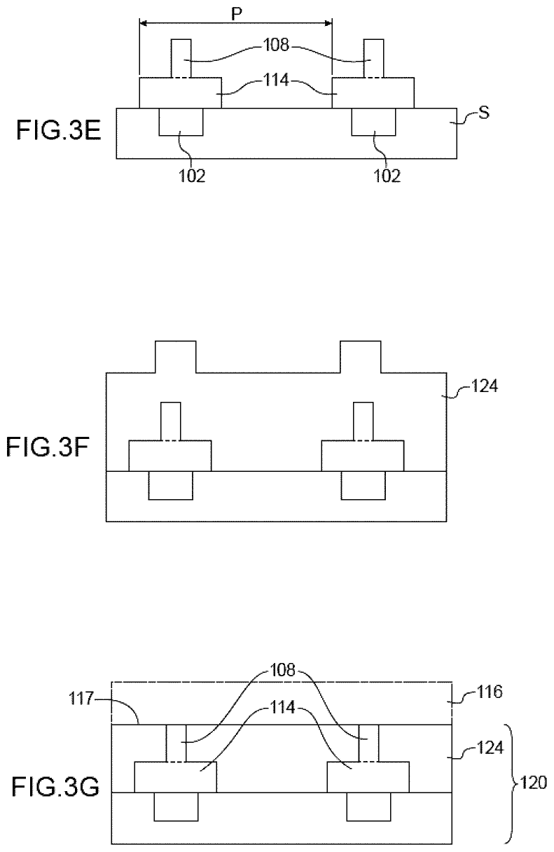

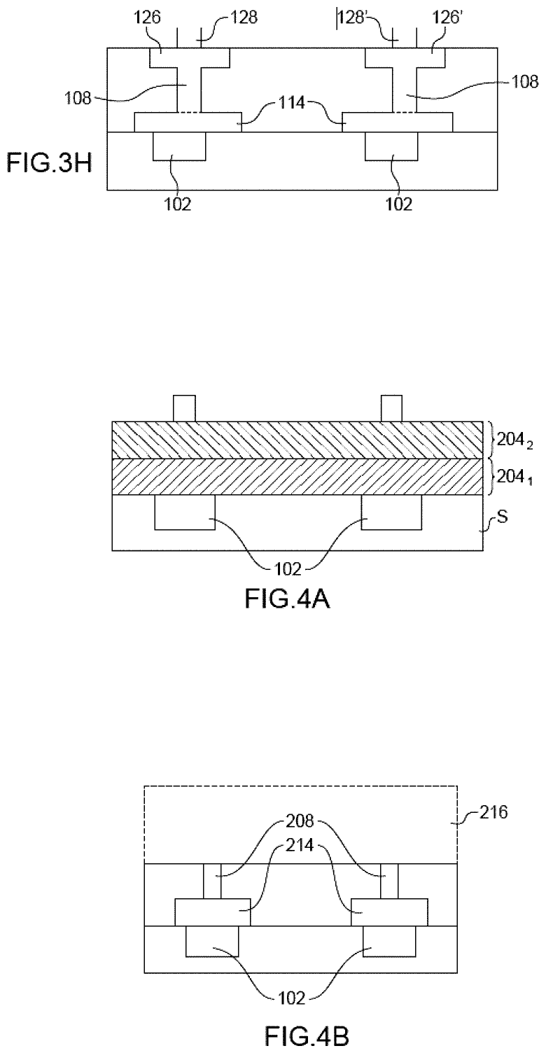

An example embodiment of a method according to the invention is shown in FIGS. 3A-3G.

On a substrate S, for example of dielectric material such as SiO₂, and which may comprise at least part one of or components of a circuit, for example contact studs 102, a deposit is made of a layer 104 of superconducting material (FIG. 3A).

This layer 104 has a thickness preferably equivalent or equal to the sum of the thicknesses:
of the track(s) or line(s), to produce in the part referenced 104₁ of that layer 104, which form the first metallic level (or lower level);
and of the via or vias to produce in the part referenced 104₂ of that same layer 104 and which will be in contact with the line or lines.

In this example:
the superconducting material may be niobium (Nb), but other examples of superconducting materials that may be employed are given further on;
the layer 104 is constituted by a single superconducting material, but it will be seen further on that it may comprise a first layer, or sublayer, of a first superconducting material for producing the lower metallic level and a second layer, or sublayer, of a second superconducting material, different from the first superconducting material, this second layer being in direct contact with the first layer and being provided for the production of the via or vias; this case is shown by the dashed lines in FIGS. 3A-3G, the first layer or sublayer of a first superconducting material being identified by the reference 104₁, the second layer or sublayer of a second superconducting material, being identified by the reference 104₂.

Next on this layer 104 is produced a resist (hard or of resin) 106 for the purpose of carrying out etching of the via or vias.

After partial etching of the layer 104 and removal of the resist, the structure of FIG. 3B is thus obtained which comprises the metallic core of the vias 108 (etched in the part referenced 104₂ of the initial layer 104) on the part referenced 104₁ in which the lower lines will be produced (after a later etching step). As this step is carried out by partial etching of the superconducting layer, it leaves part thereof intact.

In this case, mentioned above and also described in connection with FIGS. 4A-4B, in which the layer 104 comprises 2 sublayers of different superconducting material, the reference 104₁ of FIGS. 3A and 3B designates the first layer or sublayer of a first superconducting material (for producing the lower metallic level) and the reference 104₂ designates the second layer or sublayer of a second superconducting material, different from the first superconducting material, this second layer being in direct contact with the first sublayer and being provided for production of the via or vias.

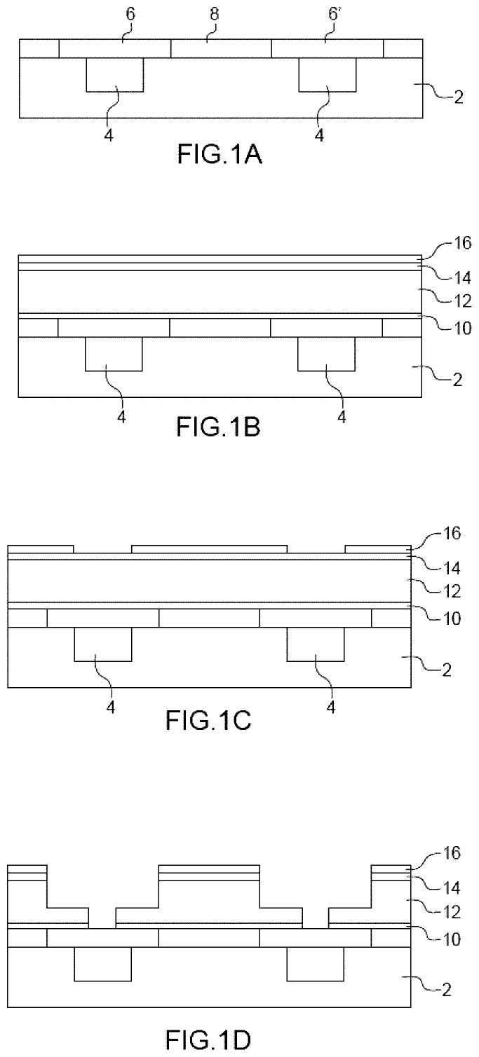

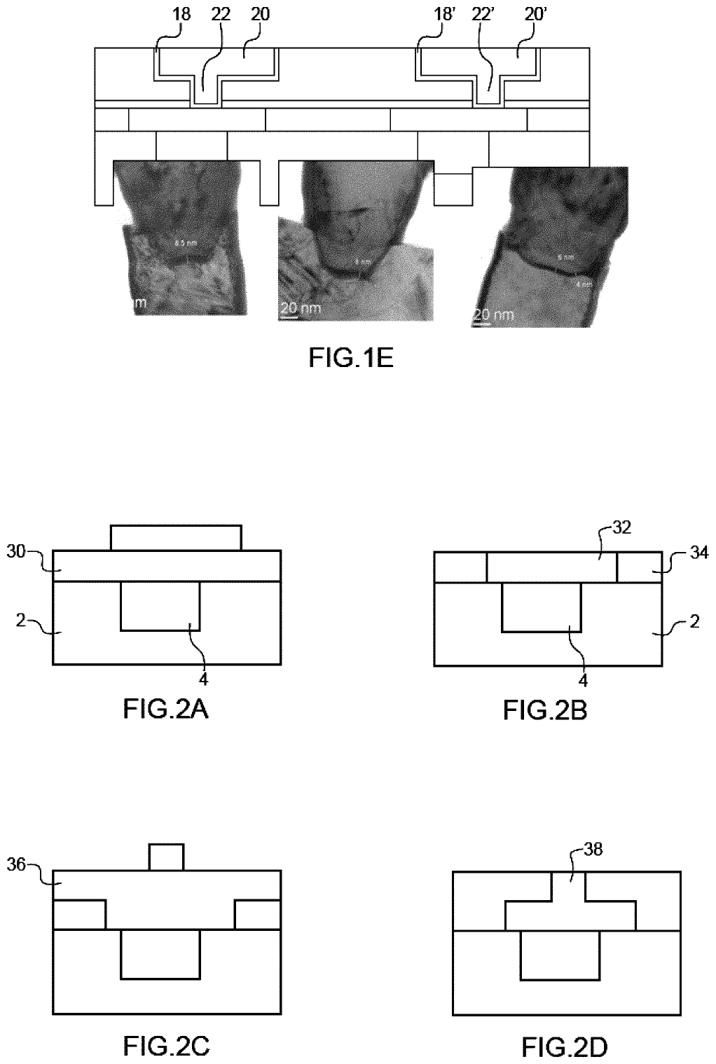

For the purpose of achieving the definition of the lines of the lower level, the part referenced 104₁ of the initial layer 104 as well as the metallic core of the vias 108 will be covered with a resin layer 110 and with a layer 112 of BARC “Bottom Anti Reflectant Coating”) or SOC (“Spin on Carbon”) type. A photolithography step (FIG. 3C) then of etching the resin layer 110 (FIG. 3D) but also of the part referenced 104₁ of the initial layer 104 (FIG. 3E) enable definition of the metallic track or tracks 114 of the lower level. At least one such metallic track 114 may be in contact with, for example, at least part of or a component of a circuit produced in the substrate S, for example a contact stud or studs 102. This step may be carried out by lithography with total etching of the exposed parts of the superconducting layer, reaching the substrate S. The etching of this step may be followed by a cleaning step. The assembly may be covered with a dielectric layer 124 (FIG. 3F), which is then planarized (FIG. 3G) for example down to the level of the upper part of the via(s). A new substrate 120 is then formed of which the upper surface 117 comprises alternating zones of dielectric material and zones of superconducting material. A second track (or line) level (or upper level) of superconducting material may be formed on this upper surface 117, these tracks being in direct contact with the vias 108. Concerning the dielectric material 124, it preferably has a low dielectric constant k; for example k<7. It may be chosen from the following list SiN, SiCN, SiO₂, SiCOH or porous SiCOH. If a porous “Low-k” material is chosen, the technique according to the invention does not give rise to modification of the properties of that material, contrary to the known “damascene” approach (described above in connection with FIGS. 1A-1E).

The steps described above (FIGS. 3A-3G) may be iterated on that substrate 120: it is also possible to deposit on the upper surface 117 an upper metallic level comprising at least one metallic layer 116 (FIG. 3G) of superconducting material the thickness of which will depend on the presence or absence of another level of vias above that upper metallic level. The sequence of steps described above starting from FIG. 3A can therefore be performed again; for example, a step of photolithography, then etching makes it possible to form the tracks 126, 126′ of the upper level (FIG. 3H). Optionally, one are more of the vias 128, 128′ are formed prior to the tracks 126, 126′. FIG. 3H represents a structure (an interconnect device) obtained with a method according to the invention, in which vias 108 connect lines 114 of a metallic level below and lines 126, 126′ of a metallic level above.

The superconducting material used in a method or a device according to the invention may be niobium; as a variant that may for example be chosen from the following list (after each material, one or 2 possible techniques for deposit have been indicated, a possible temperature or temperature range for that deposit, and, possibly, a annealing temperature range): V₃Si (PVD at ambient temperature, annealing at 500-900° C.), CoSi₂ (PVD at ambient temperature, anealing at 600-900° C.), Nb₃Ge (PVD at ambient temperature), TiN (PVD or CVD at a temperature between ambient temperature and 400° C.), NbN (PVD or CVD at ambient temperature, annealing at 500-900° C.), Al (PVD at a temperature between ambient temperature and 450° C.), TaN (PVD at ambient temperature between 20 and 90° C. or CVD, with a maximum temperature of 400° C.).

In this example embodiment and in the variant or variations disclosed below:
in the case of TiN, the etching is for example carried out by chlorine chemistry; reference may also be made to the paper by J. Tonotani et al. entitled “Dry etching characteristics of TiN film using Ar/CHF₃, Ar/Cl₂, and Ar/BCl₃ gas chemistries in an inductively coupled plasma” which appeared in the Journal of Vacuum Science & Technology B: Microelectronics and Nanometer Structures Processing, Measurement, and Phenomena 21, 2163 (2003); doi: 10.1116/1.1612517;
in the case of NbN, the etching is for example carried out by a fluorine-containing gas (for example based on SF₆ or CF₄).

Reference may also be made to the paper by Qing Zhong, et al. entitled “Study of Dry Etching Process Using SF₆ and CF₄/O₂ for Nb/NbₓSi₁₋ₓ/Nb Josephson-Junction Fabrication” 978-1-4673-0442-9/12/$31.00, July 2012, IEEE, p. 46-47; CPEM Digest (Conference on Precision Electromagnetic Measurements), DOI:10.1109/CPEM. 2012.6250653.

The person skilled in the art will adapt the etching conditions indicated above and/or in the papers cited above to etch the various levels and/or to etch other materials, including for the variants disclosed below.

As a variant of the method or a device according to the invention described above, it is possible to use 2 different superconducting materials (FIG. 4A) for one or more of the superconducting layers 104, 116:
a first superconducting material to form a first layer 204₁, for the purpose of producing lines of the lower metallic layer.
and a second superconducting material, different from the first, to form a second layer 204₂, for producing the vias.

Each of these superconducting materials may be chosen from the list given above. This variant enables better control for stopping etching (by the upper surface of the layer 204₁) when etching the vias 208. The sequence of the steps is then that described above in connection with FIGS. 3B-3G and leads to the structure of FIG. 4B, in which the superconducting material constituting the vias 208 is in direct contact with the superconducting material constituting the lines 214. It is then possible to form an upper metallic level comprising a metallic layer 216 (FIG. 4B) of a superconducting material or comprising 2 superconducting sub-layers (as in FIG. 4A) of which the total thickness will depend on the presence or absence of a via upper level. A structure identical to that of FIG. 3H can thus be obtained with 2 different superconducting materials, for example one for the metallic tracks 114, 126, 126′ and the other for the vias 108, 128, 128′. Advantageously, the second superconductor of the second sub-layer 204₂ for producing the vias is TiN or TaN. As a matter of fact, the inventors have found that the superconducting quality of these materials degraded much less than that of other superconducting materials with the reduction in the dimensions of the material. One or other of these materials thus maintains good properties once the vias have been formed. Furthermore, these materials can easily be integrated in a microelectronics process. Advantageously in association with the TiN or TaN, the first superconducting material 204₁ provided to form the lines is aluminum which is also easy to integrate and which has good etching selectivity relative to that of TiN or TaN.

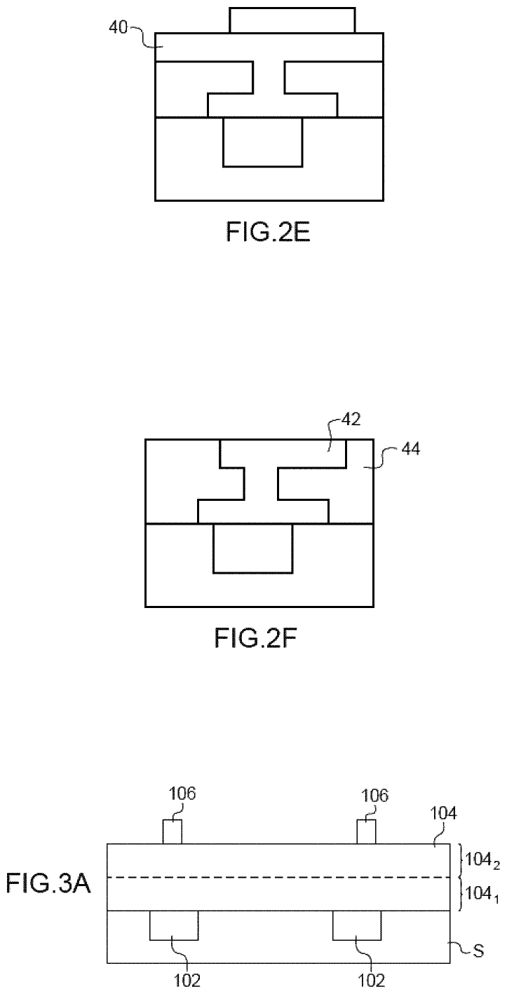

Whatever the embodiment of a method or a device according to the invention:
fewer steps are implemented than the technique described above in connection with FIGS. 2A-2F; as a matter of fact, in the course of a same step, a metallic level is defined (in a single superconducting material or in two superconducting materials) in which lines are formed, but also vias;
a superconducting member of inverted T-shape is produced (see FIGS. 3F and 3G in which the tracks of the lower line are formed after the vias), the technique described above in connection with FIGS. 1D and 1E first of all producing a T-shape, with, furthermore, the problems of contact already referred to above and linked to the presence of the layer 18, 18′.

Whatever the embodiment implemented, the invention makes it possible to produce:
a plurality, or even a network, of tracks having a pitch p (FIG. 3E) less than 1 urn, or less than 500 nm, or comprised between 500 nm and 56 nm, or which may go down to approximately 50 nm; this pitch p measures, parallel to the surface of the substrate S on which the metallic deposit is produced, the distance between identical or similar parts of 2 neighboring tracks;
one or more tracks 114 having a height H₁, measured from said surface of the substrate and perpendicular to it, comprised for example between 40 nm and 300 nm; the vias 108 may have a height H₂, measured in the same direction, comprised between H₁ and H₁/2.

1. Interconnect device for interconnection between lines of superconducting material at least one via in contact with those lines, comprising:
a) a first substrate, which carries at least one first line of a first superconducting material;
b) at least one first via of a second superconducting material, different from the first superconducting material, said at least one first line being disposed between said first substrate and said first via;
c) at least one second line above said first via and in contact with the latter.

2. Device according to claim 1, each superconducting material being chosen from V₃Si, CoSi₂, Nb₃Ge, TiN, NbN, Al, and TaN.

3. Device according to claim 1, the first superconducting material being of aluminum, and the second superconducting material being TiN or TaN.

4. Device according to claim 1, further comprising a dielectric material covering of said first line.

5. Device according to claim 4, the dielectric material being:
of low dielectric constant k<7;
and/or chosen from the following list: SiN, SiCN, SiO₂, SiCOH or porous SiCOH.

6. Device according to claim 1, comprising several first lines, with a pitch less than 500 nm, preferably comprised between 56 nm and 500 nm.

7. Device according to claim 1, comprising at least one first line of thickness H₁ comprised between 40 nm and 300 nm.

8. Device according to claim 1, said at least one first line having a thickness H₁ and at least one via, in contact with said first line, being of thickness comprised between H₁ and H₁/2.

9. Device according to claim 1, said first substrate comprising at least part of a circuit, for example at least one contact stud, with which said first line is in contact.

10. Method for producing lines of superconducting material and vias in contact with those lines, comprising:
a) forming, on a first substrate, a first superconducting layer of at least one superconducting material, of a thickness at least equal to the thickness of a first line and of a first via;
b) etching said first superconducting layer to form first of all at least one first via;
c) then etching said layer to form at least one first line between said first substrate and said first via; the first superconducting layer comprising a first sub-layer of a first superconducting material, in which said first line is produced and a second sub-layer of a second superconducting material, different from the first superconducting material, in which said via is produced.
d) forming at least one second line above said first via and in contact with the latter.

11. Method according to claim 10, each superconducting material being chosen from V₃Si, CoSi₂, Nb₃Ge, TiN, NbN, Al, and TaN.

12. Method according to claim 10, the sub-layer of said first superconducting material, in which said first line is produced, being of aluminum, and the second sub-layer of said second superconducting material being of TiN or TaN.

13. Method according to claim 10, the etching of the first superconducting layer to form said via being stopped on the upper surface of said first sub-layer of a first superconducting material.

14. Method according to claim 10, step d) of forming at least one second line comprising forming in advance at least one second via, then the second line.

15. Method according to claim 10, further comprising, between steps c) and d), a step of covering said first line with a dielectric material, forming a second substrate.

16. Method according to claim 15, the dielectric material having a low dielectric constant k<7.

17. Method according to claim 15, the dielectric material being chosen from the following list: SiN, SiCN, SiO₂, SiCOH or porous SiCOH.

18. Method according to claim 15, step d) comprising:
depositing on the second substrate a second superconducting layer of at least one superconducting material, of thickness at least equal to the thickness of a second line, and optionally a second via;
etching the second superconducting layer to optionally form the second via, and to form at least said second line, in contact with said first via.

19. Method according to claim 10, step b) being carried out by partial etching of said first superconducting layer, leaving part of that layer intact.

20. Method according to claim 10, step c) being carried out by lithography with total etching of the exposed parts of said first superconducting layer reaching the substrate.
